(19) United States
(12) Patent Application Publication
(10) Pub. No.: US 2007/0176265 A1
(43) Pub. Date: Aug. 2, 2007

(54) Substrate processing apparatus

(75) Inventor: Satoshi Takano, Toyama Shi (JP)

Correspondence Address: WENDEROTH, LIND & PONACK, L.L.P., 2033 K STREET N. W., SUITE 800, WASHINGTON, DC, 20006-1021, US

(73) Assignee: HITACHI KOKUSAI ELECTRIC INC., Tokyo (JP)

(21) Appl. No.: 10/572,478

(22) PCT Filed: Nov. 26, 2004
(86) PCT No.: PCT/JP04/17982

§ 371 Date: Jan. 9, 2007

(30) Foreign Application Priority Data
Dec. 1, 2003 (JP) 2003-401910

(51) Int. Cl. H01L 29/06

(52) U.S. Cl. 257/618

(57) ABSTRACT

A substrate processing apparatus, in which each process chamber has a different process time, loads substrates into the process chambers at fixed intervals and does not produce substrate dwell at the process chambers. It is equipped with a conveyor chamber forming a substrate convey space, a plurality of process chambers, each of which has a different substrate process time and in which substrate processing by each can be carried out in parallel and in which processing of a substrate is carried out by each in order, and substrate convey means provided in the conveyor chamber having the function of conveying substrates; also, with respect to one or more processes of conveying a substrate from one process chamber to another process chamber, with time intervals at which substrates are loaded into the same process chamber being fixed, and after processing of a substrate by one process chamber is finished the substrate is conveyed to another process chamber, a substrate convey control means controls the process of substrate convey by the substrate convey means so that compared to a standard convey time required for said convey process, a longer time is taken to complete the convey process.

### TECHNICAL FIELD

The present invention relates to a substrate processing apparatus and so forth that processes substrates, and it particularly relates to such a substrate processing apparatus that loads substrates into process chambers at set intervals and does not give rise to substrate dwell in a process chamber, even when the process time in each process chamber is different.

### BACKGROUND ART

Substrate processing apparatuses such as for example semiconductor manufacturing apparatuses that perform prescribed processing of semiconductor substrates (wafers) and LCD (Liquid Crystal Display) manufacturing apparatuses that perform prescribed processing of glass substrates for LCDs, are provided with a plurality of process chambers, and in each process chamber a substrate process such as film formation is carried out. Also, transfer machines are used to convey substrates between process chambers.

Patent Document 1
Unexamined Patent Application Publication No. Hei 11-102953

Patent Document 2
Unexamined Patent Application Publication No. Hei 10-199960

However, in the case of a conventional substrate processing apparatus in which, for example, the process time in each process chamber is different, it gives rise to the problem of variations in the intervals at which substrates are loaded into the process chambers, or substrate dwell at the process chambers, causing problems such decreases in production capability due to the variations in the intervals at which the substrates are loaded into the process chambers, problems of excess thermal histories caused by substrate dwell in process chambers, and problems of difficulty correlating single-film performance.

The present invention was accomplished to solve such conventional problems, and has as its object to provide a substrate processing apparatus and so forth that can load substrates into each process chamber at set intervals and does not give rise to substrate dwell in process chambers, even for example when the process time in each process chamber is different.

### DISCLOSURE OF THE INVENTION

To attain the above object, the substrate processing apparatus according to the present invention continuously processes a plurality of substrates, as follows, in a configuration equipped with a conveyor chamber constituting a substrate convey space, a plurality of process chambers, each of which has a different substrate process time, and substrate processing by each can be carried out in parallel, and processing of a substrate is carried out by each in order, and substrate convey means provided in the conveyor chamber having a function of conveying substrates.

That is, with time intervals at which substrates are loaded into the same process chamber being fixed, with respect to one or more processes of conveying a substrate from one process chamber to another process chamber, a substrate convey control means controls the process of substrate convey by the substrate convey means so that when, following the ending of processing of a substrate by one process chamber, said substrate is conveyed to another process chamber, the time taken to complete the convey process is longer than a standard convey time required for said convey process.

Therefore, since the time intervals at which substrates are loaded can be fixed, it is possible to prevent variations in substrate loading time intervals, even when the length of time required by each process chamber to process a substrate is different, in addition to which the substrate can be prevented from dwelling in the process chamber by retracting a partially processed substrate mounted at a place other than the process chamber in the waiting time between process chambers, for example.

Various numbers may be used as the number of the plurality of process chambers.

Also, various orders may be used as the order in which a substrate is processed in each process chamber.

Also, as the time intervals at which substrates are loaded into each process chamber, for example, the same fixed time interval may be used with respect to all process chambers.

Also, as the mode of performing a convey process in which, with respect to one or more processes of conveying a substrate from one process chamber to another process chamber, the time taken is longer than a standard convey time, for example, a mode of performing the convey process may be used in which the time taken is longer than a standard convey time in respect of all convey processes between process chambers, or a mode may be used in which the time taken is longer than a standard convey time in respect of a portion of the convey processes between process chambers. Specifically, when there is a plurality m of process chambers P(1), P(2), . . . , P(m), for example, with respect to the respective j (j=1˜(m−1)) thereof, the process of convey from process chamber P(j) to process chamber P(j+1) is set to use a mode of performing the convey process in which the time taken is longer than a standard convey time, or to perform the convey process at the standard convey time.

The standard convey time represents the time required for the process of substrate convey by the substrate convey means, for example, in cases in which there is no particular consumption of extra time. Moreover, since in an actual apparatus the length of time required for a substrate convey process will vary depending on apparatus configuration and processing conditions and so forth, the standard convey time does not have to be viewed as a strict value; the standard convey time may for example be viewed as a normal value or average value or the like.

Also, various lengths of time may be used as the length of the time that is longer than the standard convey time. For example, a fixed length of time may be set for each combination of process chamber P(j) from which convey starts and convey destination process chamber P(j+1), such as in said “process of convey from process chamber P(j) to another process chamber P(j+1).”

Also, as the mode of controlling the substrate convey process so that the time taken to complete the convey process is longer than the standard convey time, for example, a mode may be used whereby said longer time is consumed by just the convey by the substrate convey means, or a mode may be used whereby in addition to the convey by the substrate convey means, said longer time is consumed by placing a substrate at another place or the like.

As an example of one configuration, the substrate processing apparatus of the present invention is equipped with a mounting portion where a substrate is placed that is separate from the process chambers. Also, the substrate convey control means adjusts the time taken by the convey process by temporarily mounting at the mounting portion the substrate subject to the convey process.

Therefore, for example, it is possible to adjust the length of time taken for the process of conveying a substrate from one process chamber to the next process chamber by the substrate being retrieved from one process chamber by the substrate convey means, the substrate being conveyed by the substrate convey means and the substrate being placed at a prescribed mounting portion, the substrate being retrieved from the mounting portion by the substrate convey means, the substrate being conveyed by the substrate convey means and the substrate being placed in the next process chamber. That is, the length of time of a sequence of convey processes can be adjusted by adjusting the length of time and the like a substrate is left at the mounting portion.

Various types of mounting portion may be used; for example, there may be used a preliminary chamber provided separately from the process chambers, or a load-lock chamber or the like.

As an example of one configuration of the substrate processing apparatus of the present invention, the substrate convey means has a mounting portion where a substrate is placed. Also, the substrate convey control means adjusts the time taken by the convey process by temporarily mounting the substrate subject to the convey process at the mounting portion of the substrate convey means and stopping operation of the substrate convey means.

Therefore, for example, it is possible to adjust the length of time taken for the process of conveying a substrate from one process chamber to the next process chamber by the substrate being retrieved from one process chamber by the substrate convey means, the substrate being left at a mounting portion of the substrate convey means during the convey of the substrate and the operation of the substrate convey means being stopped, after which the operation of the substrate convey means is restarted and the substrate is placed in the next process chamber by the substrate convey means. That is, the length of time of a sequence of convey processes can be adjusted by adjusting the length of time and the like a substrate is left at the mounting portion.

Here, various types of mounting portion may be used as the mounting portion of the substrate convey means.

As an example of one configuration of the substrate processing apparatus of the present invention, the substrate convey means performs a rotation operation when conveying a substrate. Also, when a substrate subject to a convey process is being conveyed by the substrate convey means, the substrate control means adjusts the time taken by the convey process by controlling the speed of the convey operation of the substrate convey means including the rotation operation.

Therefore, for example, it is possible to adjust the length of time taken for the process of conveying a substrate from one process chamber to the next process chamber by the substrate being retrieved from the one process chamber by the substrate convey means, the substrate being conveyed by the substrate convey means at an adjusted operating speed and the substrate being placed at the next process chamber. That is, the length of time of a sequence of convey processes can be adjusted by adjusting the speed of the substrate convey operation by the substrate convey means.

As the convey operation of the substrate convey means including the rotation operation here, for example, a mode of adjusting just the rotation operation may be used, or a mode of adjusting rotation operation speed and speed of other operations may be used.

As an example of one configuration of the substrate processing apparatus of the present invention, as the time intervals at which substrates are loaded into each process chamber, a fixed time interval that is the same for all process chambers may be used.

As an example of one configuration of the substrate processing apparatus of the present invention, the above-mentioned standard convey time represents the time required for the process of substrate convey by the substrate convey means in cases in which there is no particular consumption of extra time.

As an example of one configuration of the substrate processing apparatus of the present invention, there is the following configuration equipped with preliminary chambers. That is, with respect to a plurality of processes performed on substrates, a critical convey timing path is determined whereby substrates are unloaded from process chambers in order from the process with the longest process time to the process with the shortest, the time in this case from the start of a convey to the aforementioned process with the longest process time (start of convey for substrate loading) to the end of a convey from a process with the shortest process time (end of convey for substrate unloading) is obtained, the result of adding to this time the minimum required retraction time at the aforementioned preliminary chamber (minimum preliminary chamber retraction time) is obtained, and this result is taken as the substrate loading time interval. Moreover, a minimum preliminary chamber retraction time does not have to be provided, which is to say it may be zero (0).

As an example of another configuration of the substrate processing apparatus of the present invention, there is the following configuration equipped with preliminary chambers. That is, with respect to a plurality of processes performed on substrates, a critical convey timing path is determined whereby substrates are loaded into process chambers in order from the process with the shortest process time to the process with the longest, the time in this case from the start of a convey to the aforementioned process with the shortest process time (start of convey for substrate loading) to the end of a convey from the process with the longest process time (end of convey for substrate unloading) is obtained, the result of adding to this time the minimum required retraction time at the aforementioned preliminary chamber (minimum preliminary chamber retraction time) is obtained, and this result is taken as the substrate loading time interval. Moreover, a minimum preliminary chamber retraction time does not have to be provided, which is to say it may be zero (0).

A method of performing the foregoing various processes can also be achieved with the present invention.

As one example, in a substrate processing apparatus equipped with a conveyor chamber forming a substrate convey space, a plurality of process chambers, each with a different substrate process time and in each of which substrate processing can be carried out in parallel, with processing of each substrate being carried out in order, and substrate convey means provided in the conveyor chamber having a function of conveying substrates that continuously processes a plurality of substrates, a semiconductor device is manufactured as follows with a method of manufacturing a semiconductor device according to the present invention.

That is, with the time intervals at which substrates are loaded into the same process chamber being fixed, with respect to one or more processes of conveying a substrate from one process chamber to another process chamber, when, following processing of a substrate by one process chamber, the substrate is being conveyed to another process chamber, a substrate convey control means controls the process of substrate convey by the substrate convey means so that the time taken to complete the convey process is longer than a standard convey time required for the convey process.

Below, further examples of configurations of the present invention are described.

As an example of one configuration, one or two or more preliminary chambers are provided as mounting portions separate from the process chambers. The preliminary chambers can, for example, be provided with a mode that enables accommodation of the number of substrates that can be processed at one time by all of the process chambers.

As an example of one configuration, substrates are temporarily retracted to a preliminary chamber between processes by the process chambers. Moreover, in cases in which substrate convey processes overlap when there is no retraction time between one process chamber and the next process chamber, either of the convey processes can be omitted; that is, a substrate can be conveyed directly from said one process chamber to said next process chamber.

As an example of one configuration, time intervals at which substrates are loaded (prescribed retraction interval), retraction times prior to processing, and retraction times after processing, with respect to a plurality of process chambers, are set in order from the longer process time of each process chamber, or with respect to a plurality of process chambers, are set in order from the shorter process time of each process chamber.

As an example of one configuration, a state of there being no substrate in either process chamber (all-retracted state) is generated periodically in the intervals at which substrates are loaded into the process chambers. For example, processing is performed once in each of all the process chambers in the interval between one all-retracted state and the next all-retracted state.

As an example of one configuration, a timer counting means is provided that counts the time in a convey by the substrate convey means, and in response to the completion of the convey by the substrate convey means and the completion of the counting of a prescribed time by the timer counting means, moves to the next convey operation. As the prescribed time here, there can be used, for example, the maximum time required for convey by the substrate convey means.

As an example of one configuration, a load-lock chamber is used as the mounting portion. The load-lock chamber can, for example, be provided with a mode that enables accommodation of the number of substrates that can be processed at one time by all of the process chambers.

As the substrates, there can be used, for example, silicon wafers or glass substrates for manufacturing semiconductor devices and LCD apparatuses.

### BRIEF DESCRIPTION OF DRAWINGS

FIG. 1 is a drawing of an example of a configuration of the substrate processing apparatus according to an embodiment of the present invention.

FIG. 2 (A) is a drawing for explaining an example of a method of calculating retraction intervals and forward-backward retraction times, (B) is a drawing showing an example of a time chart when processing one substrate, (C) is a drawing showing an example of a time chart when processing a plurality of substrates, (D) is a drawing for explaining an example of another configuration, in a case in which a minimum preliminary chamber retraction time is provided.

FIG. 3 (A) is a drawing for explaining an example of a method of calculating retraction intervals and forward-backward retraction times, (B) is a drawing showing an example of a time chart when processing one substrate, (C) is a drawing showing an example of a time chart when processing a plurality of substrates, in a case in which a minimum preliminary chamber retraction time is not provided.

FIG. 4 (A) is an example of a continuous processing flow in which a portion of the temporary retractions can be omitted, (B) is an example of a continuous processing flow in which a portion of the temporary retractions is omitted.

FIG. 5 (A) is a drawing showing an example of the content of the operation of a transfer machine, (B) is a drawing for explaining variations in times of conveys by transfer machines.

FIG. 6 is a drawing showing an example of the control of a convey operation performed by a substrate processing apparatus.

FIG. 7 is a drawing for explaining an example of a method of determining the convey speed of a transfer machine.

FIG. 8 is a drawing showing an example of a substrate processing apparatus configuration.

FIG. 9 (A) is a drawing showing an example of the flow of a substrate convey, (B) is a drawing that shows an example of a substrate processing history as an event time chart.

FIG. 10 (A), (B), (C) are drawings showing examples of event time charts in the case of the processing of a plurality of substrates.

### BEST MODE FOR CARRYING OUT THE INVENTION

An embodiment of the present invention will now be described with reference to the drawings.

This embodiment is explained with respect to the examples of a substrate processing apparatus that processes semiconductor substrates and a semiconductor device manufacturing method, but the same kind of configuration and operation can be applied to, for example, substrate processing apparatuses and the like that process LCD substrates.

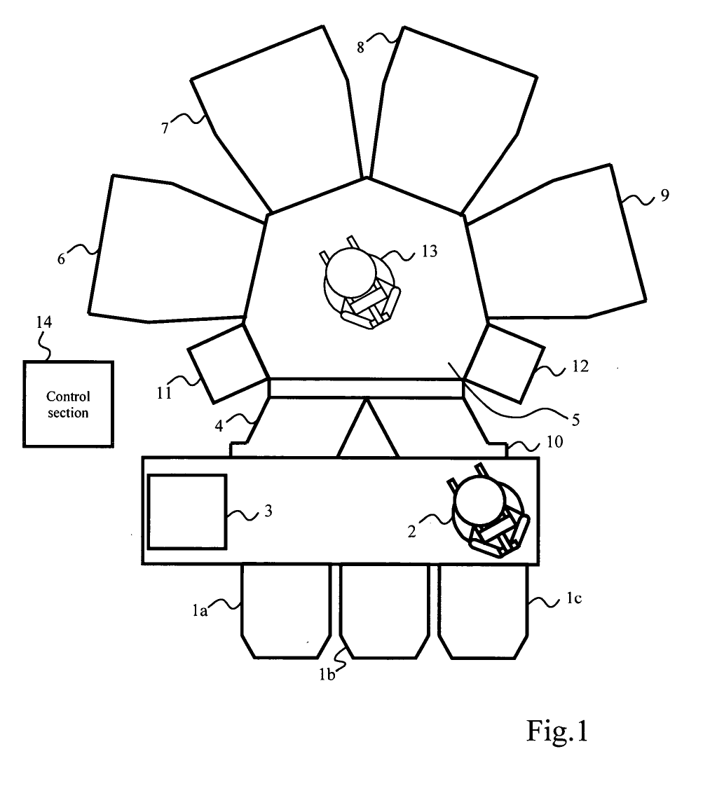

FIG. 1 shows an example of a configuration of the substrate processing apparatus according to an embodiment of the present invention.

The substrate processing apparatus of this example comprises carrier stations (load ports: LP) 1a, 1b, 1c, a transfer machine (LH) 2 for air-atmosphere use, a substrate alignment unit (aligner: AU) 3, a first load-lock chamber (LM1) 4, a conveyor chamber 5 provided with a transfer machine (TH) 13 for vacuum-atmosphere use, a first process chamber (PM1) 6, a second process chamber (PM2) 7, a third process chamber (PM3) 8, a fourth process chamber (PM4) 9, a second load-lock chamber (LM2) 10, a first preliminary chamber 11, a second preliminary chamber 12, and a control section 14.

Components here comprise two or more (four, in this example) of process chambers 6˜9 that perform prescribed processing of substrates adjoining the periphery of a centrally disposed conveyor chamber 5 equipped with a transfer machine 13 that conveys substrates, and for substrate exchanges between the conveyor chamber 5 and the outside, load-lock chambers 4, 10 for replacing the atmosphere with an inert gas such as N2 and preventing air components from entering the process chambers 6˜9. There are also carrier stations 1a, 1b, 1c for temporarily setting carriers holding substrates during processing, a transfer machine 2 for conveying single substrates at any time from a carrier above the carrier stations 1a, 1b, 1c to the load-lock chambers 4, 10, and a substrate alignment unit 3 for precisely positioning substrates in the carrier in the load-lock chambers 4, 10. The conveyor chamber 5 is also provided with preliminary chambers 11, 12 that can temporarily retract substrates. There is also a control section 14.

In this example the preliminary chambers 11, 12 are designed to be able to retract the total number of substrates that can be processed at one time by all of the process chambers 6˜9. In the example of this configuration, for example, the process chambers 6˜9 can each process one substrate, so the process chambers 6˜9 can process a total of four substrates, so the two preliminary chambers 11, 12 are constructed to be able to each retract two substrates, enabling all of the preliminary chambers 11, 12 to retract a total of four substrates.

This example shows one in which two preliminary chambers 11, 12 are provided. However, the number of preliminary chambers may be arbitrary. For example, a configuration may be used in which just one preliminary chamber retracts substrates, or a configuration may be used in which two or more preliminary chambers are used simultaneously to retract substrates.

In this example, also, the load-lock chambers 4, 10 are each provided with multistage supports that enable them to temporarily hold numerous substrates.

Also, the process chambers 6˜9 are each configured as, for example, a film formation chamber, or buffer chamber or the like.

Also, in this example the control section 14 is configured to execute a prescribed program using hardware resources such as ROM (Read Only Memory), RAM (Random Access Memory), and CPU (Central Processing Unit).

### Embodiment 1

A first embodiment of the present invention is described.

An example of a substrate processing procedure carried out by the substrate processing apparatus of this example is described.

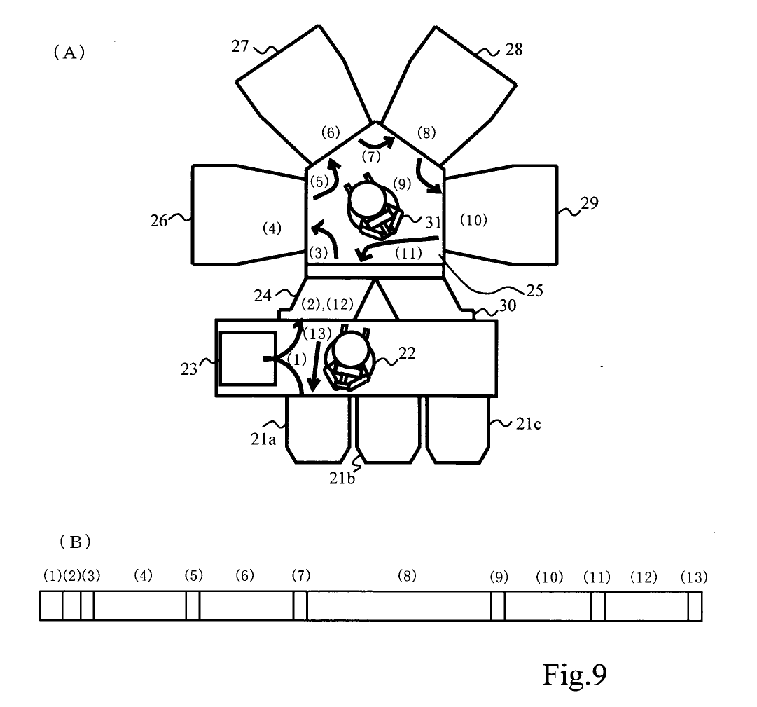

Furthermore, this embodiment is described with reference to time charts and the like showing only the parts of a vacuum convey system (for example, the parts corresponding to processes (3)˜(11) shown in FIG. 9) that are the parts specifically related to the present invention.

The substrate processing apparatus of this example is specifically characterized in that after the prescribed processing by each of the process chambers 6˜9 is concluded, the substrates are not directly conveyed to the next of the process chambers 6˜9, the substrates being conveyed to the preliminary chambers 11, 12 set up in this example and the substrates temporarily retracted between processes by each of the process chambers 6˜9.

As one example, while in the convey flow in the case of substrate processing by the four different process chambers PM1˜PM4, the processing order was “LM (load-lock chamber), PM1, PM2, PM3, PM4, LM” in the prior art example, in this example the processing order is “LM, PM1, preliminary chamber, PM2, preliminary chamber, PM3, preliminary chamber, PM4, LM.”

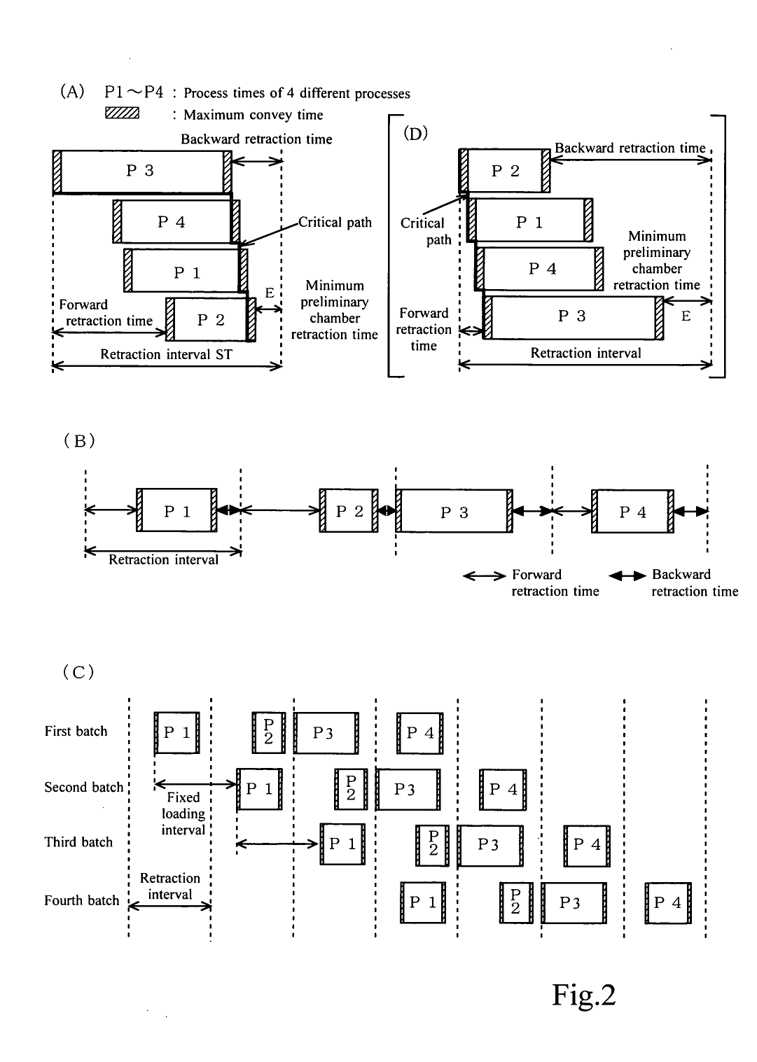

The timing chart at the time of the above convey flow of this example is explained with reference to FIG. 2. In this example, a temporary retraction type fixed tact system is used as the convey control system.

With this system, broadly speaking, after processing by each of the process chambers 6˜9 is concluded, the next process is carried out after the interposing of a retraction event. Also with this system, the retraction interval is determined from the longest process time among the different process times in the process chambers 6˜9 and the number of continuous processes, and the forward-backward retraction times (forward retraction time, backward retraction time) of each process are calculated from the retraction interval. Also, variations in substrate loading intervals and process chamber dwell are eliminated by adjusting the time of retraction events. In this example, the retraction interval shows the periodic interval of the periodic arrival of a state in which there are no substrates in all of the process chambers 6˜9.

An example of a method of calculating the retraction interval and forward-backward retraction times will be described with reference to FIG. 2 (A).

Further, in this embodiment, P1, P2, P3, P4 each show the respective different process or process time of the four process chambers 6, 7, 8, 9. Also, the convey time (the diagonally shaded portions in the drawing) indicate the maximum time required for the convey.

With the method of calculating the retraction interval of this example, first, with respect to the plurality of processes P1 ˜P4 performed on substrates, a critical convey timing path (state in which shortest convey is possible) is determined whereby substrates are unloaded from the process chambers 6˜9 in order from the process with the longest process time to the process with the shortest, and the result of adding to this critical path in which processing is efficiently carried out in this order the minimum necessary retraction time (minimum preliminary chamber retraction time) with the preliminary chambers 11, 12 that can be arbitrarily set as required is taken as the retraction interval.

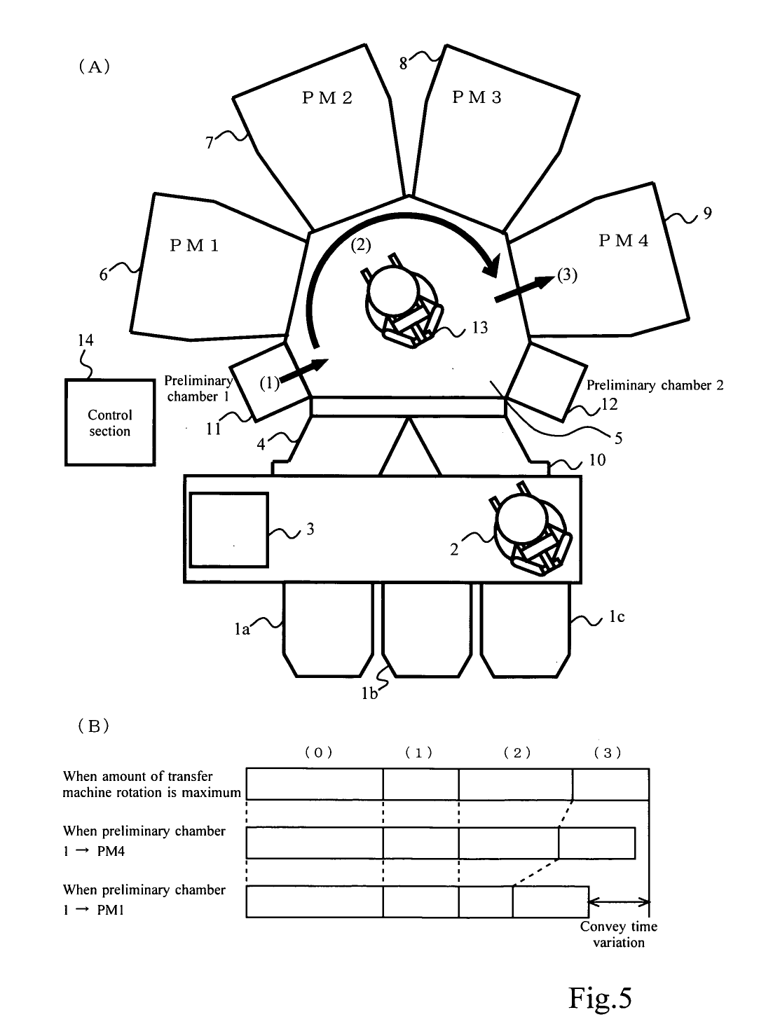

Specifically, if n is the number of continuous processes, Pmax is maximum process time, T is maximum convey time between process chambers, and E is the minimum retraction time of preliminary chambers 11, 12, the retraction interval ST is expressed by (Equation 1). Moreover, the convey time between process chambers will be the total time required for the sequence of processes ((1)˜(3) or (0)˜(3)) shown in FIG. 5 (B), for example.

When the retraction interval ST is determined, if Pi (i=1˜n) is each process time and X is the order of length of process times (X=1 in the case of the longest process time, and X=n in the case of the shortest process time), the forward retraction time of each process is expressed by (Equation 2) and the backward retraction time is expressed by (Equation 3).
Retraction interval ST=Pmax+T×(n+1)+E (Equation 1)
Forward retraction time of process Pi=ST−Pi−{(n+2−X)×T}−E (Equation 2)
Backward retraction time of process Pi=(n−X)×T+E (Equation 3)

In the case of the substrate processing apparatus of this example, the number of continuous processes n=4, the order from longest to shortest process time is P3 (X=1), P4 (X=2), P1 (X=3), P2 (X=4), and the maximum process time Pmax=P3.

FIG. 2 (B) shows the event time chart, which shows the timing of each processing event arranged in the substrate processing order on the basis of the retraction interval, when the forward-backward retraction times of each of the processes P1˜P4 have been determined. That is, it is the combinations of the forward-backward retraction times for each of the processes P1˜P4 and the process times by each of the process chambers 6˜9 arrayed in succession in the order of substrate processing, depicting the substrate processing history as dimensional events.

Specifically, with respect to the number of continuous processes n, the process flow of the processing order “forward retraction 1, process 1, forward retraction 2, process 2, backward retraction 2, forward retraction 3, process 3, backward retraction 3, . . . , forward retraction n, process n, backward retraction n” is formed.

FIG. 2 (C) shows a time chart representing the timing of each process in the case of continuous processing of a plurality of substrates.

As shown in the figure (C), with substrates being loaded at the same time intervals (loading intervals) as the retraction interval ST, the result of overlaying the event time chart shown in figure (b) is that the time intervals at which substrates are loaded into each of the process chambers 6˜9 can be fixed and dwelling of substrates in the process chambers 6˜9 can be prevented, with no convey or process chamber interference.

The example shown here is of a configuration that can execute a critical path in respect of substrate convey by arraying the process times in order from the longer, calculating the retraction intervals and efficiently conveying the substrates in order from the longer process times. However, it is also possible to use a configuration (here called configuration A) such as the one shown in FIG. 2 (D), for example, that can execute a critical path in respect of substrate convey by arraying the process times in order from the shorter, calculating the retraction intervals and efficiently conveying the substrates in order from the shorter process times, and an effect similar to that of this example can be obtained.

Specifically, if in the above configuration A n is the number of continuous processes, Pmax is the maximum process time, T is the maximum convey time between process chambers, and E is the minimum retraction time of the preliminary chambers 11, 12, the retraction interval ST is shown by (Equation 4).

When the retraction interval ST is determined, if Pi (i=1˜n) is each process time and X is the order of length of process times (X=1 in the case of the shortest process time, and X=n in the case of the longest process time), the forward retraction time of each process is expressed by (Equation 5) and the backward retraction time is expressed by (Equation 6).
Retraction interval ST=Pmax+T×(n+1)+E (Equation 4)
Forward retraction time of process Pi=(X−1)×T (Equation 5)
Backward retraction time of process Pi=ST−Pi−(X+1)×T (Equation 6)

In the case of the substrate processing apparatus of this example, the number of continuous processes n=4, the order from shortest to longest process time is P2 (X=1), P1 (X=2), P4 (X=3), P3 (X=4), and the maximum process time Pmax=P3.

### Embodiment 2

A second embodiment of the present invention is described.

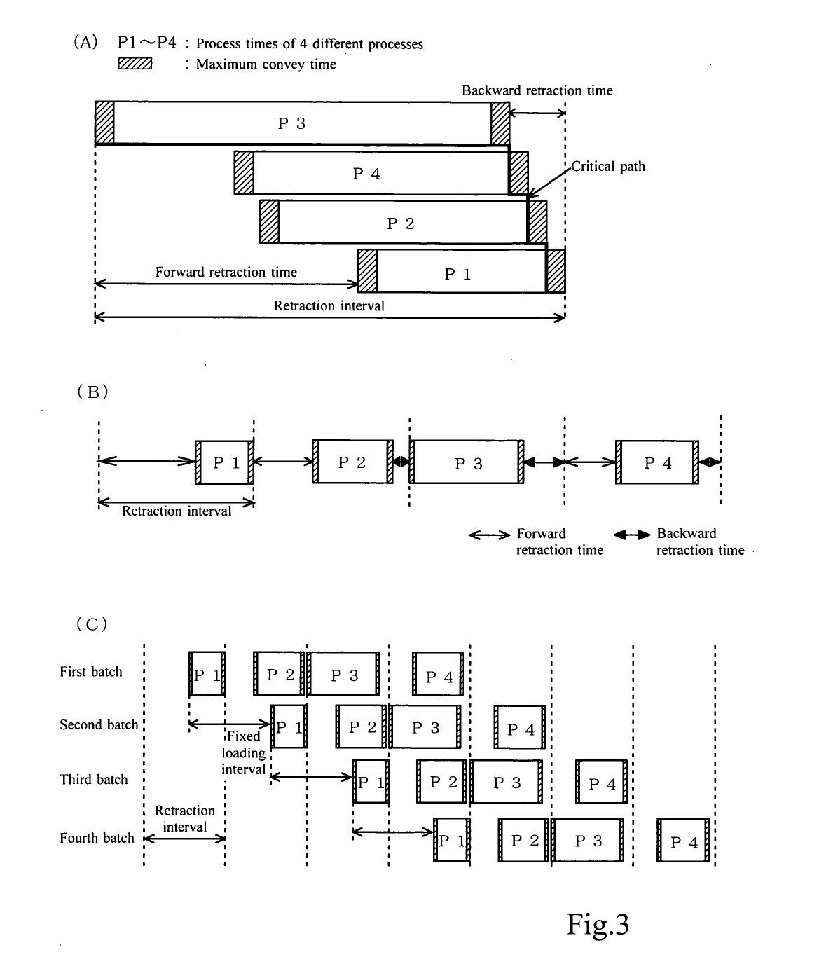

FIG. 3 (A), (B), (C) are drawings similar to those shown by FIG. 2 (A), (B), (C), in respect of a case in which the minimum preliminary chamber retraction time E is omitted, that is, E=0. Retraction interval ST and forward-backward retraction times can be calculated by, for example, using E=0 in equations similar to those shown in the case of FIG. 2 (A), (B), (C). Moreover, FIG. 3 (A), (B), (C) show examples in a case in which the relationships of the lengths of time of the processes P1˜P4 are different compared to the examples of FIG. 2 (A), (B), (C).

### Embodiment 3

A third embodiment of the present invention is described.

As an applied example of the event time chart shown in FIG. 2 (C), even if temporary retractions are partially omitted, under the condition that each of the process times P1˜P4 is fixed, a similar effect can be obtained and can contribute to improving convey efficiency.

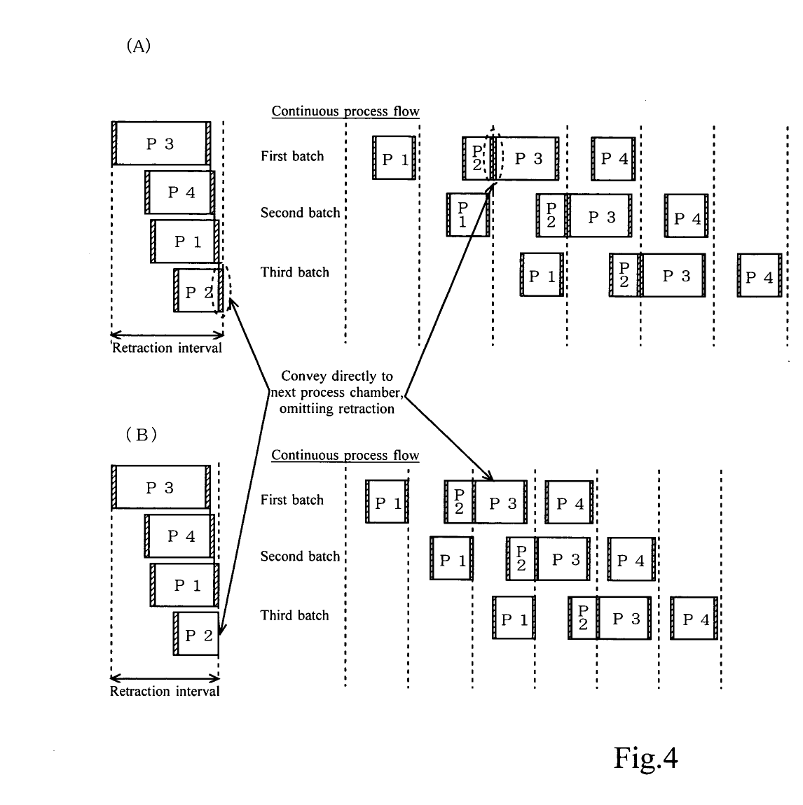

FIG. 4 (A) shows an example of an event time chart in a case in which it is possible to omit a portion of the temporary retraction processes, in respect of which FIG. 4 (B) shows an example of an event time chart in which a portion of the temporary retraction processes is omitted.

Specifically, in the case of the event time chart shown in FIG. 4 (A), the step of process P3 having the largest process time and the step of process P2 having the smallest process time are performed continuously in the continuous processing flow. Because of this, the convey after a process P2 and the convey before a process P3 overlap.

Therefore, in the event time chart shown in FIG. 4 (B), one of the two overlapping conveys, for example the convey after process P2, is omitted, forming a continuous processing flow in which after process P2, the substrate is conveyed directly to the process chamber of the next process P3. This enables convey efficiency to be improved.

Here, as the condition that enables omission of temporary retraction as in this example, there is for example the condition that in the processing sequence the sum of the forward retraction time of the ith process and the backward retraction time of the (i−1)th process is zero, or the condition that in the processing sequence the sum of the backward retraction time of the ith process and the forward retraction time of the (i+1)th process is zero. When such a condition applies, it is possible for conveys to be performed continuously, omitting temporary retraction between two processes.

### Embodiment 4

A fourth embodiment of the present invention is described.

The example described in the foregoing was one in which the length of convey times between each of the process chambers 6˜9 was considered to be fixed (a fixed value calculated based on the maximum convey time), theoretically avoiding interference in terms of the event time chart. However, because in practice there exist a plurality of combinations of transfer origin and transfer destination process chambers 6˜9, the tendency is for the operation time to lengthen in proportion to the size of the amount of operation of the transfer machine.

An example of the content of the operation of the transfer machine 13, and the main causes of variations in convey time are described, with reference to FIG. 5 (A), (B).

The content of the operation of the transfer machine 13 are broadly divided into the following (0)˜(3).

(0) When the transfer machine 13 is not positioned at the transfer origin process chamber or the like, a step of rotating the transfer machine 13 to the transfer origin process chamber or the like is performed. This step is not required when the transfer machine 13 is not positioned at the transfer origin process chamber or the like.

(1) A step of a substrate in the transfer origin process chamber or the like being picked up by the transfer machine 13 is performed.

(2) A step of rotating the transfer machine 13 to the transfer destination process chamber or the like is performed.

(3) A step of placing the substrate in the transfer destination process chamber or the like is performed.

FIG. 5 (A) shows the example of a case in which a substrate is conveyed from first preliminary chamber 11 to fourth process chamber 9.

Since whether or not the above step (0) is generated is determined by the state of the preceding transfer step by the transfer machine 13, in the description of this example, in this regard, it is assumed to be the same time.

FIG. 5 (B) shows an example of an event time chart in a case in which the amount of rotation of the transfer machine 13 being the maximum, a case in which the transfer machine 13 is rotated from the first preliminary chamber 11 to the fourth process chamber 9, and a case in which the transfer machine 13 is rotated from the first preliminary chamber 11 to process chamber 6.

Generally, the operation control moves a transfer machine to the operation of the next axis of operation in accordance with the determination of the completion of the operation of each axis of operation. Differences in the transfer amounts of each axis of the transfer machine 13 causes convey time variations. Thus, as shown in FIG. 5 (B), when a comparison is made with respect to a case in which a substrate is actually conveyed from the first preliminary chamber 11 to the first process chamber 6 and a case in which a substrate is conveyed from the first preliminary chamber 11 to the fourth process chamber 9, the convey time variations is produced that corresponds to the amount of rotation operation of the transfer machine 13. That is to say, even if forward-backward retraction times calculated with reference to FIG. 2 and the like are consumed by the preliminary chambers 11, 12, because maximum convey time T is used as the convey time, the result of actual convey time variations arising at the transfer destination of the transfer machine 13 is that the intervals at which substrates are loaded into the process chambers 6˜9 are no longer fixed.

Moreover, while this example is described with respect to rotation operation, which generally is the most pronounced factor in convey time variations, in a case in which, for example, each of the process chambers 6˜9 has a different configuration, it is preferable to also take into consideration the effect and the like of differences in transfer strokes to the process chambers.

Also, although the above variations in convey times are usually in the order of at most several seconds, improvement thereof is preferable, because the substrates are dwelling in a process chamber, and, moreover, to control the substrate processing history.

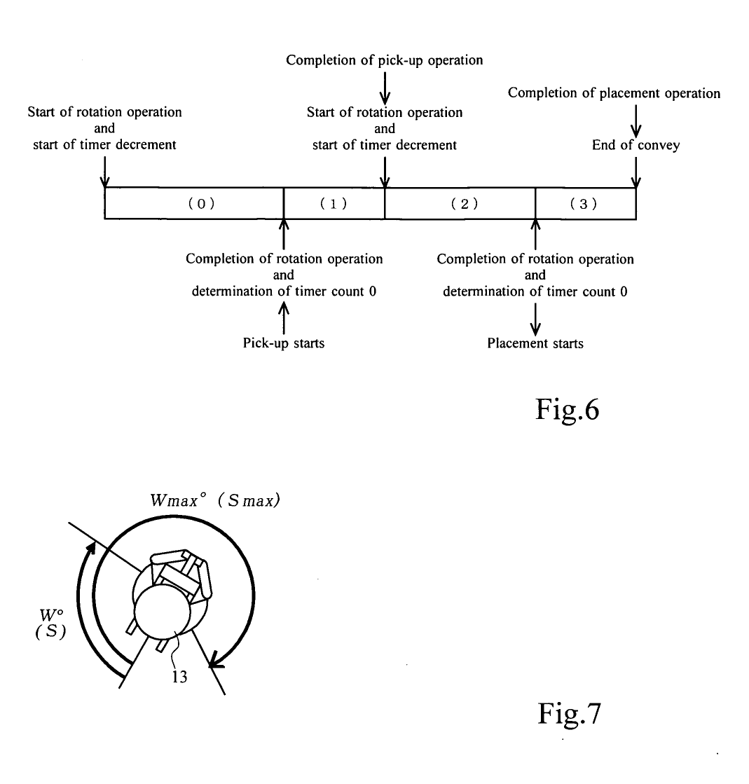

FIG. 6 shows an example of the control of convey operations by the transfer machine 13 in the substrate processing apparatus of this example, in order to prevent the above convey time variations. In this example, this is shown with respect to rotation operation, which is the most pronounced variation factor.

The convey operation of the transfer machine 13 of this example is controlled by the control section 14. In the convey operation control of this example, monitoring is conducted by an arbitrary time value together with the start of the rotation operation of the transfer machine 13; when both the elapse of a predetermined time and a determination that the rotation operation is concluded are satisfied, the next operation, for example substrate pick-up or placement, is started. The maximum time required for the rotations (maximum rotation time), for example, can be used as said predetermined time.

Specifically, in the example of FIG. 6, first, when rotation operation (0) of the transfer machine 13 starts, decrementing of a prescribed timer count value (for example, a value larger than zero) starts, and in accordance with a determination that rotation operation (0) is concluded and a determination that the timer count value has reached zero, substrate pick-up operation (1) is started, and in accordance with a determination that substrate pick-up operation (1) is concluded, rotation operation (2) of the transfer machine 13 starts, along with which decrementing of a prescribed timer count value (for example, a value larger than zero) starts, and in accordance with a determination that rotation operation (2) is concluded and a determination that the timer count value has reached zero, substrate placement operation (3) is started, and in accordance with a determination that substrate placement operation (3) is concluded, the substrate convey operation is considered to be concluded.

By doing this, the timing of the loading of substrates into the process chambers 6˜9 becomes constant at all times, even when actual rotation operations by the transfer machine 13 are quickly concluded, so it is possible to prevent variations in the heat history of the substrates. Furthermore, from the standpoint of convey efficiency, it is preferable to use the actual maximum convey operation value as the timer monitoring value relating to the axial operations of the transfer machine 13.

### Embodiment 5

A fifth embodiment of the present invention is described.

Concerning the control described with reference to FIG. 5 or FIG. 6 and, furthermore, with respect to the transfer machine 13, it is possible to implement it as a configuration that can vary the speed of each axis operation, in order to standardize beforehand convey times in accordance with the operation amount of axis operations, for example.

An example of a method for determining the convey speed (in this example, the rotation speed) of the transfer machine 13 will be described with reference to FIG. 7.

Taking Wmax [degrees (°)] as the maximum rotation angle in the convey control of the transfer machine 13, and Smax [degrees (°)/sec] as the average rotation speed at that time (highest average rotation speed during substrate transfer), the average rotation speed S [degrees (°)/sec] when the transfer target rotation angle is W [degrees (°)] is expressed by Equation 7. In this way, in this example, taking the rotation speed at the maximum rotation angle as the maximum speed, when the rotation angle is smaller than that, the rotation speed is decreased to match the rotation time, regardless of the rotation angle.
S=W/(Wmax/Smax) (Equation 7)

### Embodiment 6

A sixth embodiment of the present invention is described.

The foregoing described an example in which, between a substrate process at one process chamber and a substrate process at the next process chamber, the substrate subject to the process (convey subject) is retracted to preliminary chambers 11, 12. As an example of another configuration, in this example, excess time between from after a substrate process at a first process chamber is concluded and the substrate is picked up by the transfer machine 13 to when the substrate is placed at the next process chamber, is consumed by stopping operation of the transfer machine 13 with the substrate subject to the process (convey subject) mounted on a plate provided on the transfer machine 13. That is, in this example, the preliminary chambers 11, 12 do not have to be provided, the transfer machine 13, not the preliminary chambers 11, 12, that is stopped forming the substrate retraction location. In this case, a plurality of the transfer machine 13 plates may be provided as required.

### Embodiment 7

A seventh embodiment of the present invention is described.

As an example of another configuration, in this example, excess time between from after a substrate process at a first process chamber is concluded and the substrate is picked up by the transfer machine 13 to when the substrate is placed at the next process chamber, is consumed by decreasing as required the speed of the rotation operation and the like of the transfer machine 13 conveying the substrate subject to the process (convey subject). That is, in this example, the preliminary chambers 11, 12 do not have to be provided, the transfer machine 13, not the preliminary chambers 11, 12, that is made to perform rotation operation or the like at a low speed forming the substrate retraction location.

### Embodiment 8

An eighth embodiment of the present invention is described.

As an example of another configuration, in this example, excess time between from after a substrate process at a first process chamber is concluded and the substrate is picked up by the transfer machine 13 to when the substrate is placed at the next process chamber, is consumed by retracting the substrate subject to the process (convey subject) to the load-lock chambers 4, 10. That is, in this example, the preliminary chambers 11, 12 do not have to be provided, the load-lock chambers 4, 10, not the preliminary chambers 11, 12, forming the substrate retraction location. In this example, moreover, the load-lock chambers 4, 10, are designed to be able to retract the total number of substrates that can be processed at one time by all of the process chambers 6˜9.

As shown in the above embodiments (embodiment 1˜embodiment 8), the substrate processing apparatus according to the present invention has a conveyor chamber 5 forming a substrate convey space, a group of process chambers which are connected to said conveyor chamber 5 that includes at least two of process chambers 6˜9 and which executes continuous and parallel processing of substrates by the process chambers 6˜9, with each process chamber having a different substrate process time, a substrate convey apparatus (transfer machine) 13 that is a substrate convey apparatus accommodated in said conveyor chamber 5 that when, after processing in one of the process chambers of the said group of process chambers is concluded, conveying a substrate to a next, different process chamber, is able to convey said substrate at a predetermined standard convey time, and a control section 14 that controls operation of said substrate convey apparatus 13. Also, with time intervals at which substrates are loaded into the same one of process chambers 6˜9 being fixed, when a substrate that has finished being processed by one of the process chambers of the said group of process chambers and is being conveyed to the next process chamber by said substrate convey apparatus 13, said control section 14 controls the substrate convey apparatus 13 so that the substrate is loaded into the next process chamber at a prescribed convey time (set convey time) that is longer than said standard convey time, whereby a plurality of substrates are continuously processed.

The substrate processing apparatus according to this embodiment also is provided with a space that is different from the processing space of the group of process chambers, and also has a mounting plate on which substrates are temporarily placed, and in cases in which a substrate is conveyed at said prescribed convey time (set convey time), the operation of the substrate convey apparatus 13 is controlled so that with respect to a time zone that is longer than said standard convey time, the substrate that is the convey subject is placed on the mounting plate.

Also, as an example of one configuration, the substrate convey apparatus according to this embodiment is equipped with preliminary chambers 11, 12 as a mounting plate.

Also, as an example of another configuration, the substrate processing apparatus according to this embodiment has a plate on which the substrate convey apparatus 13 places substrates. In cases in which a substrate is conveyed at said prescribed convey time (set convey time), the operation of the substrate convey apparatus 13 is controlled so that with respect to a time zone that is longer than said standard convey time, the operation of the substrate convey apparatus 13 is stopped with the substrate that is the convey subject held on the plate. That is, in this configuration example, retraction time is consumed not by substrate retraction to the above-described preliminary chambers 11, 12, but by the plate of the substrate convey apparatus 13 that is a separate means.

Also, as an example of another configuration of the substrate processing apparatus according to this embodiment, when a substrate is conveyed at said prescribed convey time (set convey time), the operation of the substrate convey apparatus 13 is controlled so that with respect to a time zone that is longer than said standard convey time, the substrate that is the convey subject is conveyed at a state at which at least the rotation operation time of the substrate convey apparatus 13 is made slower (the prescribed time is lengthened) than the rotation operation time that operates at said standard convey time. That is, in this configuration example, retraction time is consumed not by substrate retraction to the above-described preliminary chambers 11, 12, but by the substrate convey apparatus 13 that is a separate means.

It is also possible to provide a method for achieving the various processes performed by the substrate processing apparatus according to this embodiment; for example, a method and the like of manufacturing a semiconductor device and so forth can be provided.

Below, further specific configuration examples relating to this embodiment are described.

In a configuration of the substrate processing apparatus according to this embodiment that is equipped with a conveyor chamber 5 equipped with one transfer machine 13, at least two of process chambers 6˜9 for the purpose of heat treatment or ultrathin film formation, and load-lock chambers 4, 10 for the purpose of air-atmosphere and conveyor chamber 5 atmosphere replacement, a semiconductor manufacturing apparatus and substrate convey control method are provided that when processing of two or more substrates is conducted in parallel in process chambers having different process times, convey substrates with the time intervals at which the substrates are loaded into each of the process chambers 6˜9 being fixed and do not produce substrate waiting times during unloading.

Also, the substrate processing apparatus of this embodiment provided with preliminary chambers 11, 12 in the conveyor chamber 5 provides a semiconductor manufacturing apparatus and substrate convey control method that temporarily retracts to the preliminary chambers 11, 12 substrates that have finished being processed by process chambers.

The substrate processing apparatus of this embodiment also provides a semiconductor manufacturing apparatus and substrate convey control method in which the total substrate stock number of the preliminary chambers 11, 12 is equivalent to a sum of the number of substrates processed at one time by the process chambers 6˜9 and the total number of process chambers 6˜9. That is, locations are provided that ensure all substrates can be retracted (number of shelves, for example).

Also, a substrate processing apparatus configuration of this embodiment in which the total substrate stock number of the load-lock chambers 4, 10 is equivalent to a sum of the number of substrates processed at one time by the process chambers 6˜9 and the total number of process chambers 6˜9, provides a semiconductor manufacturing apparatus and substrate convey control method that temporarily retracts to the load-lock chambers 4, 10 substrates that have finished being processed by process chambers. That is, locations are provided that ensure all substrates can be retracted (number of shelves, for example). Moreover, a configuration may be used that for example uses just one load-lock chamber for substrate retraction, or a configuration may be used that simultaneously uses a plurality of load-lock chambers for substrate retraction.

The substrate processing apparatus of this embodiment also provides a semiconductor manufacturing apparatus and substrate convey control method that performs substrate conveyance whereby during processing of a plurality of substrates, a state in which all substrates are in a retracted state not in the process chambers 6˜9 periodically exists in each substrate loading interval (retraction interval ST).

The substrate processing apparatus of this embodiment also provides a semiconductor manufacturing apparatus and substrate convey control method wherein, in the interval from one retraction state until the next retraction state, substrate conveyance and processing are executed at least once in all of the process chambers 6˜9, repeating the processes of “temporary retraction, substrate processing, temporary retraction.”

The substrate processing apparatus of this embodiment also provides a semiconductor manufacturing apparatus and substrate convey control method wherein, the substrate conveyance order in the interval from one retraction state until the next retraction state is the order of unloading consecutively from the longer process times of the process chambers 6˜9 without any interval, or the order of unloading consecutively from the shorter process times of the process chambers 6˜9 without any interval.

The substrate processing apparatus of this embodiment also provides a semiconductor manufacturing apparatus and substrate convey control method wherein determination of the conclusion of each axis operation of the transfer machine 13 is timer-monitored to equalize actual substrate convey times between process chambers 6˜9, load-lock chambers 4, 10, preliminary chambers 11, 12.

The substrate processing apparatus of this embodiment also provides a semiconductor manufacturing apparatus and substrate convey control method wherein the timer-monitored value determining the conclusion of axis operation of the transfer machine 13 is the maximum actual operation value of each axis.

The substrate processing apparatus of this embodiment also provides a semiconductor manufacturing apparatus and substrate convey control method that varies operation speed in accordance with the operation amount of each axis operation of the transfer machine 13 to equalize actual substrate convey times between process chambers 6˜9, load-lock chambers 4, 10, preliminary chambers 11, 12.

Therefore, with the substrate processing apparatus of this embodiment, even in parallel processing of steps by a plurality of the process chambers 6˜9 having different process times, for example, substrate convey control is possible whereby the time intervals at which the substrates are loaded into each of the process chambers 6˜9 are fixed and there is no substrate dwell in the process chambers 6˜9, making it possible to improve the quality repeatability and yield of semiconductor manufacturing devices. For example, in a heat treatment apparatus, in terms of device manufacturing steps, ultimately, to reduce superfluous heat history (thermal budget), it is preferable for a substrate subject to a process to be held in a conveyor chamber or preliminary chamber and the like maintained at around room temperature, rather than in a process chamber in which the substrate is maintained in a high-temperature state. With the processing of this embodiment, it is also easier to correlate single-film performance (thin-film quality from independent film formation by each process chamber).

The above embodiments (embodiment 1˜embodiment 8) are examples of preferred modes to which the present invention is not necessarily limited, it being possible to carry out various modifications and the like to the extent that they do not depart from the gist of the present invention.

With the substrate processing apparatus and so forth of this embodiment, also, the substrate convey means is constituted by the functions of the transfer machine 13, the substrate convey control means is constituted by the transfer machine 13 control functions of the control section 14, the functions of the mounting portion are constituted by the functions of the preliminary chambers 11, 12 or also by the functions of the load-lock chambers 4, 10, the mounting portion of the transfer machine 13 is constituted by the functions of the plate, and the timer counting means is constituted by the timer-monitoring functions of the control section 14 in respect of conveyance by the transfer machine 13.

Below, the background art relating to the present invention is described. The items described here are not necessarily all limited to the background art.

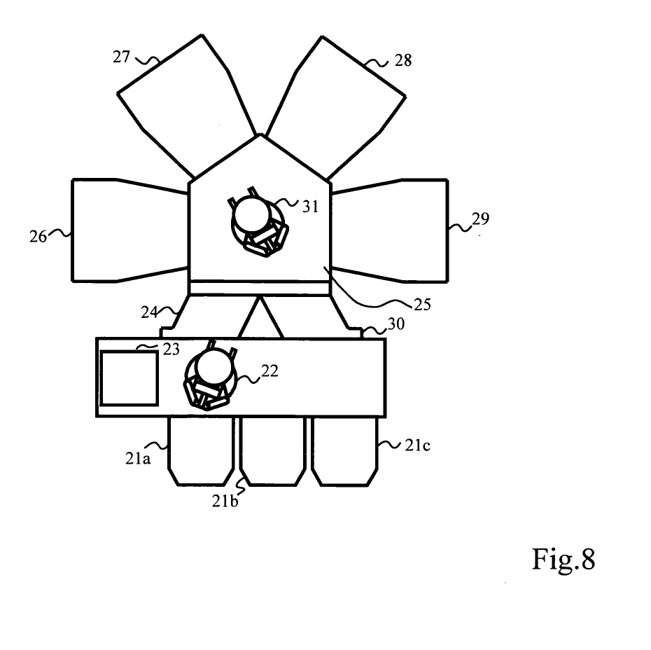

FIG. 8 shows an example of a general substrate processing apparatus configuration.

The substrate processing apparatus of this example comprises carrier stations (load ports: LP) 21a, 21b, 21c, a transfer machine (LH) 22 for air-atmosphere use, a substrate alignment unit (aligner: AU) 23, a first load-lock chamber (LM1) 24, a conveyor chamber 25 provided with a transfer machine (TH) 13 for vacuum-atmosphere use, a first process chamber (PM1) 26, a second process chamber (PM2) 27, a third process chamber (PM3) 28, a fourth process chamber (PM4) 29, and a second load-lock chamber (LM2) 30. Broadly speaking, the processing parts 21a˜21c, 22˜31, have the functions to perform operations similar to those of the corresponding processing parts shown in FIG. 1. Heat treatment process furnaces may be used for the process furnaces (process chambers 26˜29); specifically, hot-wall furnaces, lamp furnaces, resistance-heating plate system cold-wall furnaces and the like may be used.

An example of the substrate processing procedure by the substrate processing apparatus shown in FIG. 8 is described, with reference to FIG. 9.

FIG. 9 (A) shows an example of substrate convey flow of one process substrate in a case in which multilayer films of ultrathin films are formed via process chambers 26˜29, FIG. 9 (B) shows an example of the processing history of the substrate as an event time chart. In the figure (A) and figure (B), the same numbers (1) ˜(13) are mutually applied.

Below, the processes (1) ˜(13) of the substrate process flow are described, in order.

(1) In the load (air-atmosphere convey) process step, substrates in the carrier station 21a are conveyed one by one to the first load-lock chamber 24 by the transfer machine 22 for air-atmosphere use.

In this example, center position alignment and rotational position alignment of the substrate are carried out via the substrate alignment unit 23 to improve repeatability of convey positioning to the first load-lock chamber 24.

(2) In the load-lock chamber evacuation process step, evacuation, N2 atmosphere replacement are carried out to prevent air from entering the conveyor chamber 25. In line with the retained pressure region of the conveyor chamber 25 (1.0E˜5.0E 4 Pa), after evacuation, a supply of inert gas such as N2 is used to adjust the pressure.

(3) In the first substrate convey process step, the vacuum-atmosphere-use transfer machine 31 of the conveyor chamber 25 is used to convey the substrate from the first load-lock chamber 24 to the first process chamber 26. In addition, the substrate is subjected to film formation processing such as ultrathin film formation, heat treatment and other such processes by the process chambers 26˜29. Usually, also, in most cases the process time in the process chambers 26˜29 is different in each of the process chambers 26˜29.

(5) In the second substrate convey process step, the vacuum-atmosphere-use transfer machine 31 of the conveyor chamber 25 is used to convey the substrate from the first process chamber 26 to the second process chamber 27.

(6) In the second process processing step, processing is carried out in the second process chamber 27.

(7) In the third substrate convey process step, the vacuum-atmosphere-use transfer machine 31 of the conveyor chamber 25 is used to convey the substrate from the second process chamber 27 to the third process chamber 28.

(8) In the second process processing step, processing is carried out in the third process chamber 28.

(9) In the fourth substrate convey process step, the vacuum-atmosphere-use transfer machine 31 of the conveyor chamber 25 is used to convey the substrate from the third process chamber 28 to the fourth process chamber 29.

(10) In the fourth process processing step, processing is carried out in the fourth process chamber 29.

(11) In the fifth substrate convey process step, the vacuum-atmosphere-use transfer machine 31 of the conveyor chamber 25 is used to convey the substrate from the fourth process chamber 29 to the first load-lock chamber 24.

(12) In the load-lock chamber atmospheric pressure return process and substrate cooling process step, atmospheric pressure is restored to return the processed substrate to an air-atmosphere, which simultaneously doubles as a post-processing high-temperature substrate cooling event.

(13) In the unload process step, the processed substrate is conveyed from the first load-lock chamber 24 to the carrier station 21a.

In the event time chart shown in FIG. 9 (B) the substrate processing history is arranged as dimensional events in respect of the above steps (1) ˜(13).

In order to continuously and efficiently perform the same process on a plurality of substrates, an arrangement is required whereby there is no overlapping of the same events in the above time chart.

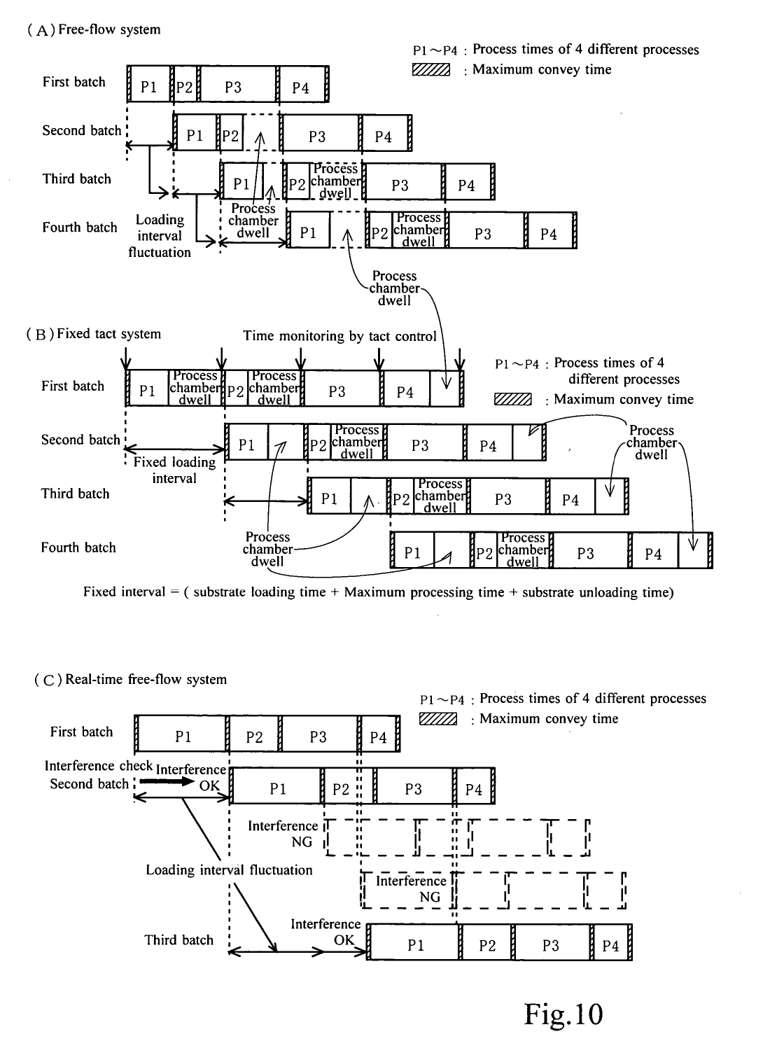

FIG. 10 (A), (B), (C) show examples of event time charts in the case of the processing of a plurality of substrates. These are examples of substrate convey control being used since before. In the time charts of this example, only the parts of the vacuum convey system that are parts specifically related to the present invention are shown (the parts corresponding to the processes (3) ˜(11) shown in FIG. 9). Also, P1, P2, P3, P4 each show the respective different process or process time of the four process chambers 6, 7, 8, 9. Also, the convey time (the diagonally shaded portions in the drawing) indicate the maximum time required for the convey.

FIG. 10 (A) shows an example of a free-flow system.

In this method, each event proceeds through the execution of a sequence in the order in which it is determined that an event has been completed by the conclusion of processing by the process chambers 26˜29 or the conclusion of substrate conveyance. Also, only the degree of priority in the case of a simultaneously determination is defined; the order of conveys is not particularly specified. As the degree of priority, information is set such as for example “with respect to loading and unloading, give priority to unloading.”

However, with this method, in cases in which process times of the process chambers 26˜29 are different, the intervals at which the process chambers 26˜29 are loaded fluctuate, and even after prescribed processing by the process chambers 26˜29 of short process time items is concluded, transfer to the next convey event may be impossible due to other rate-determining processes, so that as a result, unintended irregular dwelling is produced in the process chambers 26˜29. That is, variations in loading intervals arise, and convey waiting during substrate unloading, giving rise to process chamber dwell. Also, from substrate to substrate, loading intervals and process chamber dwell times are irregular, degrading substrate performance repeatability in severe heat treatment steps.

FIG. 10 (B) shows an example of a fixed tact system (see, for example, Patent Document 1).

With this system, in all conveys the convey sequence is executed using starting timing as a set time. Also, loading interval fluctuations and variations in dwell time by the process chambers 26˜29 are controlled by taking the maximum process time of the process chambers 26˜29 and, from the convey times, the most rate-determining process as the loading interval and optimizing in line with the longest process time of all of the substrate convey operations. Specifically, the substrate loading interval corresponds to (substrate loading time+maximum process time+substrate unloading time), and time monitoring is performed by tact control at a prescribed timing corresponding to the loading interval (the timing denoted in the figure by the arrows) This gets rid of loading interval fluctuations and variations in process chamber dwell times, eliminating superiority between substrates.

However, in cases predicated on process times by each of the process chambers 26˜29 being different, because this system requires that substrates dwell at the process chambers 26˜29, superfluous heat history is produced in the substrates, and it is also difficult to correlate single-film performance.

FIG. 10 (C) shows an example of a real-time free-flow system (see, for example, Patent Document 2).

With this system, interference of the process chambers 26˜29 or convey interference is checked in real-time, the next batch is loaded at a timing at which there is no interference, and the sequence starting from the loading is executed in accordance with a free-flow system that is event-completion-determination based. Specifically, from the start of the processing of the first substrate, there is constant checking for interference by the same process events performed by the process chambers 26˜29, and by convey events, and the next substrate is loaded at a timing at which interference is not produced.

However, with this system there are cases in which the intervals at which substrates are loaded into the same one of the process chambers 26˜29 vary each time, and interference is frequently produced by combinations of the process times of the process chambers 26˜29, markedly slowing the loading intervals and degrading productivity.

Here, there are times when it is confirmed that the above loading interval fluctuations and dwelling inside the process chambers have an adverse effect on substrate quality. In operations up to the present, the substrate convey control systems shown in FIG. 10 (A), (B), (C) have been used selectively, taking into consideration the degree of the adverse effects on substrate quality.

An adverse effect when there are variations in the intervals at which substrates are loaded into the process chambers 26˜29 has shown up, for example, in thermal CVD (Chemical Vapor Deposition) apparatuses and the like as a variation in film thickness in the order of 1˜2%. With a thermal CVD apparatus, it is difficult to directly monitor and control substrate temperature, because reaction gas adheres to the temperature sensor, so in most cases indirect monitoring and control of the heating element that heats the substrate is used. As such, even if the heating element is always maintained at a set temperature, the stable temperature of the overall process chamber will differ depending on the substrate load cycle, having an adverse effect, though small, on substrate performance. That is, in the case of a short cycle, the temperature in the furnace goes down, and in the case of a long cycle, the temperature in the furnace goes down, causing the initial substrate loading temperature recovery time to change, changing substrate properties.

With respect to the effect imparted by substrate dwell in a process chamber, for example, unintended substrate dwell can increase the heat history of a substrate compared to normal processing, and risks degrading not only the steps by the processing apparatus, but even the quality of ultrathin films formed up until then.

From the background described in the above, previously, there has been a desire to develop a substrate convey control method whereby the intervals at which substrates are loaded into the process chambers 26˜29 is fixed and which does not produce substrate dwell at the process chambers 26˜29, even in cases where the process times of the process chambers 26˜29 are different.

In contrast, with the present invention, for example, in semiconductor manufacturing such as heat treatment, substrate performance repeatability can be improved by substrate conveyance with the intervals at which substrates are loaded into each process chamber being fixed that also does not produce substrate waiting times during unloading.

The configurations of the substrate processing apparatus of the present invention are not necessarily limited to those described in the foregoing, with various configurations being usable. Also, the present invention can be provided as, for example, methods or systems that execute processing in accordance with the present invention, and programs to realize such methods or systems, and recording media that records said programs, and can also be provided as various apparatuses or systems.

Also, the field of application of the present invention is not necessarily limited to that described in the foregoing, the present invention being applicable to various fields.

Also, the various types of processing performed in the substrate processing apparatus and so forth of the present invention may be constituted by being implemented in hardware resources equipped with a processor and memory and the like, for example, being controlled by means of a processor executing a control program stored in ROM (Read Only Memory), and the various functional means for executing this processing may also be constituted as independent hardware circuits.

Also, the present invention may also be understood as one wherein the above control program (itself) is stored on a Floppy® disc, CD (Compact Disc)-ROM or other computer-readable recording medium, so that the processing according to the present invention can be implemented by said control program being input from the recording medium into a computer and executed by a processor.

### INDUSTRIAL APPLICABILITY

As described in the foregoing, in accordance with the substrate processing apparatus and so forth of this invention, when continuously processing a plurality of substrates in a case in which the substrate process times of each of a plurality of process chambers are different, processing in each of the process chambers can be done in parallel, and processing of a substrate is done in order by each process chamber, when the time intervals at which substrates are loaded into the same process chamber are fixed and, as needed, after processing of a substrate by one process chamber is finished the substrate is conveyed to another process chamber, since the substrate convey process is controlled so that compared to a standard convey time required for said convey process, a longer time is taken to complete the convey process, it is possible to prevent fluctuations in the time intervals at which substrates are loaded, and it is also possible to prevent substrates dwelling in the process chambers.

1. A substrate processing apparatus for continuously processing a plurality of substrates, comprising:
a conveyor chamber in which a substrate convey space is constituted,
a plurality of process chambers, each of which has a different substrate process time and in which substrate processing by each can be carried out in parallel and in which processing of a substrate is carried out by each in order,
a substrate convey unit that conveys a substrate, the substrate convey unit being provided in the conveyor chamber, and
a substrate convey controller that controls a process of conveying a substrate by the substrate convey unit after processing of a substrate by one process chamber is finished while the substrate is conveyed to another process chamber, the controller controlling the process of conveying the substrate so that the substrates are loaded into the same process chamber at fixed time intervals, and so that compared to a standard convey time required for said convey process, a longer time is taken to complete the convey process.

2. A substrate processing apparatus as recited in claim 1, further comprising:
a mounting portion that mounts a substrate that is separate from the process chambers, and
wherein the substrate convey controller adjusts the time taken by the convey process by temporarily mounting at the mounting portion the substrate to be conveyed.

3. A substrate processing apparatus as recited in claim 1, wherein:
the substrate convey unit has a mounting portion that mounts a substrate, and
the substrate convey controller adjusts the time taken by the convey process by temporarily mounting the substrate to be conveyed at the mounting portion of the substrate convey unit and stopping operation of the substrate convey unit.

4. A substrate processing apparatus as recited in claim 1, wherein:
the substrate convey unit performs a rotation operation when conveying a substrate, and
when the substrate to be conveyed is conveyed by the substrate convey unit, the substrate convey controller adjusts the time taken by the convey process by controlling speed of convey operation including rotation operation by the substrate convey unit.

5. A substrate processing apparatus as recited in claim 1,
wherein, as the time intervals at which substrates are loaded into each process chamber, a fixed time interval that is the same for all process chambers is used.

6. A substrate processing apparatus as recited in claim 1,
wherein the standard convey time represents the time required for the process of substrate convey by the substrate convey unit in a case in which there is no particular consumption of extra time.

7. A substrate processing apparatus as recited in claim 1, further comprising a
preliminary chamber, and
substrate loading time interval is the result of adding the minimum required retraction time at the preliminary chamber to the time from start of a convey to a process with the longest process time to the end of a convey from a process with the shortest process time in a case in which, with respect to a plurality of processes performed on substrates, a critical convey timing path is determined whereby substrates are unloaded from process chambers in order from the process with the longest process time to the process with the shortest.

8. A substrate processing apparatus described in claim 1, further comprising a
preliminary chamber, and
substrate loading time interval is the result of adding the minimum required retraction time at the preliminary chamber to the time from start of a convey to a process with the shortest process time to the end of a convey from a process with the longest process time in a case in which, with respect to a plurality of processes performed on substrates, a critical convey timing path is determined whereby substrates are loaded into the process chambers in order from the process with the shortest process time to the process with the longest.

9. A semiconductor device manufacturing method of manufacturing a semiconductor device using a substrate processing apparatus that continuously processes a plurality of substrates, the processing apparatus including a conveyor chamber in which a substrate convey space is constituted; a plurality of process chambers, each of which has a different substrate process time and in which substrate processing by each can be carried out in parallel and in which processing of a substrate is carried out by each in order; and a substrate convey unit that conveys a substrate, the substrate convey unit being provided in the conveyor chamber,
the semiconductor device manufacturing method comprising controlling a process of conveying a substrate by the substrate convey unit after processing of a substrate by one process chamber is finished while the substrate is conveyed to another process chamber, so that the substrates are loaded into the same process chamber at fixed time intervals and so that, compared to a standard convey time required for said convey process a longer time is taken to complete the convey process.
